(19) United States
(12) Patent Application Publication
(10) Pub. No.: US 2006/0102465 A1
(43) Pub. Date: May 18, 2006

(54) Contacting of an electrode with a substance in vacuum

(75) Inventors: Anja Blondeel, Deinze (BE); Wilmert De Bosscher, Drongen (BE)

Correspondence Address: FOLEY AND LARDNER LLP;SUITE 500, 3000 K STREET NW, WASHINGTON, DC, 20007, US

(73) Assignee: Bekaert Vds

(21) Appl. No.: 10/550,507

(22) PCT Filed: Feb. 26, 2004
(86) PCT No.: PCT/EP04/50210

§ 371 Date: Oct. 24, 2005

(30) Foreign Application Priority Data
Mar. 25, 2003 (EP) 03100768.5

(51) Int. Cl. C23C 14/32

(52) U.S. Cl. 204/192.1

(57) ABSTRACT

A method for improving the sputter deposition process is provided. The method comprises the following steps: a) providing a vacuum; b) providing an electrode (10, 34, 34′, 44, 44′) in the provided vacuum ; c) providing a substrate in said vacuum, said substrate having no contact with said electrodes (10, 34, 34′, 44, 44′) providing a device (22, 22′, 24, 24′, 26, 26′, 28, 28′, 30, 36, 36′, 48, 48′) in the vacuum. The device is in relative motion to the electrode and is in contact with the electrode over a contact zone. The device removes solid material from the electrode or applies solid material to the electrode. The method is carried out by means of a simple mechanism. There is no need for complicated electronics or sophisticated control algorithms. The method is carried out in vacuum, i.e. there is no need to break the vacuum, so that the machine downtime is reduced.

### FIELD OF THE INVENTION

The present invention relates to a method for improving a sputter deposition process, e.g. a magnetically enhanced sputtering process. The term “improving” refers to improving the long-term plasma process stability, or to improving the coating homogeneity, or to reducing the machine downtime during sputter deposition.

### BACKGROUND OF THE INVENTION

Problem of Arcing.

In a magnetron sputter deposition process (magnetically enhanced sputtering) an array of magnets, arranged in the form of a closed loop, is mounted behind the target. A magnetic field in the form of a dosed loop is thus formed in front of the target and defines the sputtering zone. The magnetic field causes electrons from the discharge to be trapped in the field and travel in a spiral pattern, which creates a more intense ionization (plasma) and a higher sputter rate as compared to diode sputtering. A rotating cylindrical magnetron uses a cylindrical cathode as a target. In this configuration the cylindrical cathode rotates continuously over a stationary magnet array. The rotating cylindrical configurations have several advantages over a planar magnetron configuration such as a higher coating capacity due to a higher target material consumption and the fact that more target material is available, the possibility to use higher power densities, an enhanced anode functionality in AC processes and a lower arc rate in reactive processes.

Despite a lower arc rate, arcing, however, remains a major problem, especially in reactive processes. During reactive sputter deposition, a reactive gas (such as O₂ or N₂) is introduced into the sputtering chamber next to the inert gas in order to form a dielectric layer (an oxide or nitride) onto the substrate. A drawback, however, is that the dielectric layer intended for the substrate is also formed onto the target surface and especially on areas next to the race track. In case of a rotatable target, the zones next to the racetrack which are not sputtered are called the end zones.

In the rotating cylindrical magnetron assembly, the target (cathode) is rotated continuously over a stationary magnet array so that a new portion of the target is continuously presented to the sputtering zone. This implies that the target erosion zone comprises the entire circumference of the cathode. In other words, the target is continuously cleaned by the plasma except for the end zone (beyond the sputtering zone). This implies that the build up of a dielectric layer only occurs at the end zones of the rotating cylindrical target. Due to the bombardment by positive ions this dielectric layer charges up positively while the target is biased negatively. Once the charge has built to a certain level, the charge will dissipate by arcing (breakdown of the dielectric layer occurs). Arcing causes process instabilities leading to inhomogeneities and defects in the coating and may cause damage to the sputter equipment.

Groove Formation at Racetrack Turns.

A rotating cylindrical magnetron ensures an even target consumption over the entire target tube length except for the end zones of the target at the position of the race track turn where a groove is formed. At the racetrack turn, the target moves underneath the plasma for a longer time as compared to the straight part of the racetrack. This leads to higher target material consumption at the race track turns as compared to the straight part of the racetrack. Once the target material in the zones of the racetrack turns is consumed completely, the target has to be replaced although still an appreciably amount of valuable material may be present over a main part of the target.

The prior art has provided cylindrical targets in the form of a dogbone. Dogbone targets have more target material available in the zones of the race track turns. Dogbone targets avoid too early consumption of the target. Dogbones, however, are not always available and possible for all materials because of several reasons such as brittleness, heat conductivity, material cost, production process.

Poisoning of the Target.

In continuous sputtering of e.g. an ITO (Indium Tin Oxide) sputtering target in an atmosphere of an argon oxygen mixture, a black matter, called nodules will appear on the surface of the target. These nodules tend to grow. These nodules are not or less sputtered due to their insulating nature. These nodules cause arcing during sputtering and are a source of inhomogeneities and particles in the sputtered thin film. For acceptable operation, once the nodule formation and thus the arcing and reduced sputter region has become too strong, the sputter process has to be discontinued and the nodules have to be removed mechanically before restarting.

U.S. Pat. No. 6,106,681 discloses a method for cleaning an ITO sputtering target. Prior to sputtering or during standstills, the ITO sputtering target is subjected to multiple-oscillation ultrasonic washing, or alternatively, an adhesive tape is stuck to the surface of the ITO sputtering target.

### SUMMARY OF THE INVENTION

It is an object of the present invention to avoid the drawbacks of the prior art.

It is a second object of the present invention to improve the long-term plasma process stability.

It is a third object of the present invention to improve the coating homogeneity on the substrate.

It is a fourth object of the present invention to reduce the machine downtime during sputter deposition.

It is a fifth object of the present invention to further reduce arcing.

It is a sixth object of the present invention to reduce groove formation on a target.

According to a general aspect of the present invention there is provided a method for improving the sputter deposition process. The method comprises the following steps
a) providing a vacuum;
b) providing an electrode in the vacuum;
c) providing a substrate in said vacuum, said substrate having no contact with said electrode;
d) providing a device in the vacuum, this device is in relative motion to the electrode and is in contact with the electrode over a contact zone;
   the device removes material from the electrode or applies material to the electrode, the material being in a solid state.

The relative motion between the substance and the electrode and the contact between the substance and the electrode may be continuous or be intermittent. The device can for example be applied onto the rotating target in between substrate charging cycles without the need of breaking the vacuum. Or it can be in continuous contact with the electrode following the speed of the electrode—i.e. there is no relative motion between device and electrode—now and then being braked off —what generates a relative motion—when material is being removed or applied.

This method is advantageous in several respects. The method is simple. Indeed the method is carried out by means of a simple mechanism. There is no need for complicated electronics or sophisticated control algorithms. Moreover, the method is carried out in vacuum, i.e. during the sputter deposition process or as part of a sputter deposition cycle, so that the machine downtime is reduced. In addition the method can be performed in situ without the need to remove the target out of the sputtering apparatus.

The electrode may be a cathode, for example, a cylindrical target, which functions as cathode. The advantage of a cylindrical target in the context of the present invention is that the contacting device may stand still, since the cylindrical target rotates. During rotation of the cylindrical target, the device may continuously or intermittently remove or add material to the target.

The electrode may also be an anode that is not in contact with the substrate. This anode can be a cylindrical tube, which may be rotatable and which may rotate. Or it can be a metallic wire brush—such as described in U.S. Pat. No. 5,683,558 to Sieck et al.—where extremities of the metal wires act as a collector of negative charge. Such a ‘metal wire brush’ can have any shape but is preferably of a round, elongated shape. The brush can move relative to the device.

The wall or a shield of the vacuum chamber can also act as an anode. The device then has to move with respect to the stationary vacuum chamber.

In a first embodiment of the invention, material is removed from the electrode. Here the device preferably has a hardness, which is greater than or equal to the hardness of the target or part thereof. The device can—by way of example—be an abrasion means, or a cutting means, or a polishing means where the intention is to remove material from the electrode.

In a second embodiment of the invention, material is added to the electrode. Here the device preferably has a hardness, which is less than or equal to the hardness of the target or part thereof. When it is the intention to apply material to the electrode, it can—again by way of example—be done by means of a feed mechanism, or an applicator or any other device as is known in the art.

Various alternatives are also possible with respect to the contact zone between the electrode, mostly the target, and the device.

In a first alternative the contact zone overlaps with the end zone, e.g. covers the end zone, e.g. is equal to the end zone. The end zone is the zone which is not sputtered.

In a second alternative the contact zone overlaps with the zone of racetrack return, e.g. covers the zone of racetrack return, e.g. is the zone of racetrack return on the target.

In a third alternative the contact zone overlaps the erosion zone, e.g. covers the erosion zone, e.g. is the erosion zone. The erosion zone is the of normal target consumption, also the zone of straight racetracks.

Amongst others, the third alternative of the invention is particularly useful for materials that are sensitive to so-called ‘nodule’ formation. ‘Nodules’ are local irregularities that form on the surface of the target during deposition of the target material. The nodules differ in hardness or electrical conductivity form their immediate surroundings thereby disturbing the uniformity of the sputtering process. The following materials are particularly known for their sensitivity to nodule formation:

ITO—indium tin oxide—targets, or

ZnAlO—zincoxide doped with aluminium

TiN, Ti, CoTi, and Al

The method is most suited for ITO targets.

### BRIEF DESCRIPTION OF THE DRAWINGS

The invention will now be described into more detail with reference to the accompanying drawings wherein

FIG. 1A is a cross-section of a cylindrical target;

FIG. 1B is an upper view of the cylindrical target of FIG. 1A;

FIG. 2 illustrates a first example of the invention where material is applied to end zones of a target;

FIG. 3 illustrates a second example of the invention where material is removed from end zones of a target;

FIG. 4 illustrates a third example of the invention where material is applied to zones of race track return of a target;

FIG. 5 illustrates a fourth example of the invention where material is applies to both the zones of race track return and the end zones of a target;

FIG. 6 illustrates a fifth example of the invention where material is removed from an erosion zone of a target;

FIG. 7 illustrates a sixth example of the invention where material is removed from a rotating anode.

FIG. 8 illustrates a seventh example of the invention where material is removed from a rotating metal wire brush anode.

### DESCRIPTION OF THE PREFERRED EMBODIMENTS OF THE INVENTION

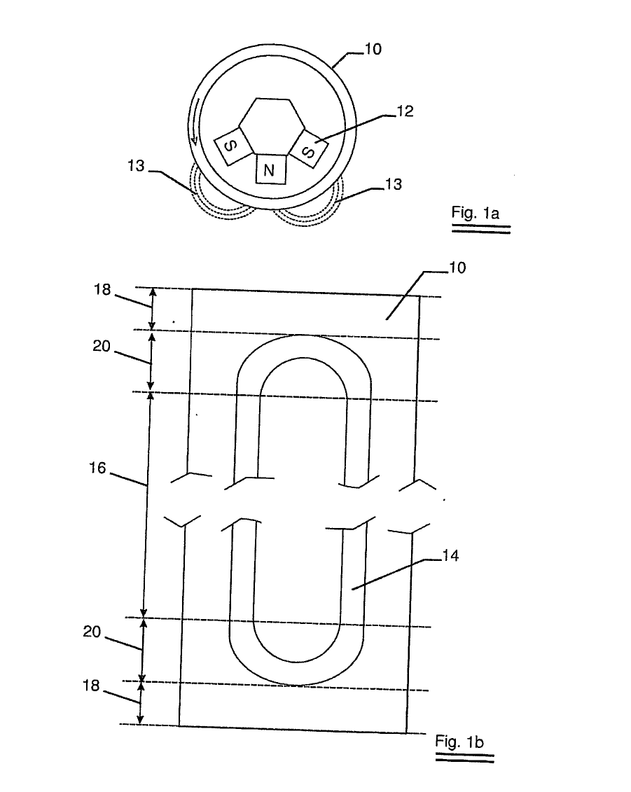

FIG. 1A is a cross-section of a rotating cylindrical target 10, which rotates around a stationary magnet assembly 12. The magnet assembly results in a magnetic field 13.

FIG. 1B is an upper view of the target 10. The combined effect of electric and magnetic forces creates a so-called racetrack 14 on the surface of the target 10. This racetrack 14 is the region where target material is sputtered.

The racetrack 14 defines three different types of zones on the target 10.

A first type of zone forms the major part and is called the erosion zone 16 and corresponds to the straight parts of the racetrack 14. In the erosion zone 16, consumption of the target material during sputtering is substantially equal.

A second type of zone can be found at the end sections and is called the end zone 18. In the end zones 18 no (or very little) target material is sputtered away, in other words, no target material is consumed in the end zones 18.

A third type of zone is the zone of racetrack return 20. As mentioned hereabove, in the zones of racetrack return 20 normally a groove is formed, since the target 10 moves underneath the plasma for a longer time as compared to the erosion zone 16. This leads to higher target material consumption in the zones of racetrack return 20 and to the creation of grooves.

The present invention provides various solutions for various problems in the different zones of a target.

### EXAMPLE 1

FIG. 2 illustrates a first example of the invention where material is applied mainly to the end zones 18 of a rotating cylindrical target 10. Left and/or right belt like material, referred to by 22 resp. 22′ is rubbed against respectively the left and right end zone 18 of the rotating target 10. The belt like material 22, 22′ can be stationary with respect to the deposition chamber, or can exercise a to and fro movement, or can move with the target, now and then being braked off in order to generate motion between target and device. The under side of the belt like material 22, 22′ is provided with a conducting material with a lower hardness than the material of the target 10. On rotation of the target 10 and due to the lower hardness of the conducting material, a layer of this conducting material is applied to the complete circumference of the end zones 18. As a result, the arc sensitive area is kept in a conducting state. No charging up occurs. Arcing is avoided.

As a matter of example, the target 10 may be of aluminum, zinc or tin, and the belt like material 22, 22′ may be provided with graphite blocs.

### EXAMPLE 2

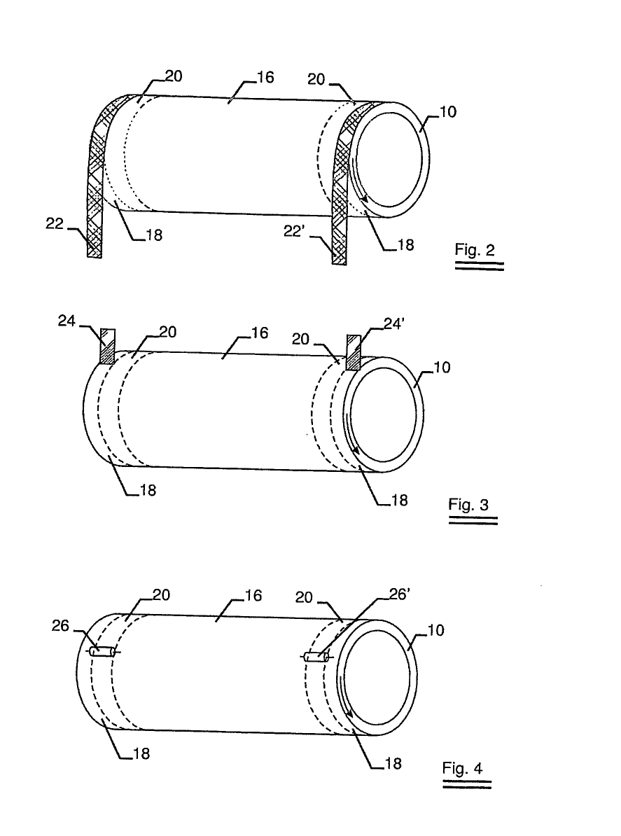

FIG. 3 illustrates a second example of the invention where material is removed mainly from end zones 18 of a rotating cylindrical target 10. Appropriate blade, knifelike or chisel cutting tools or scraping devices 24, 24′ are provided with a hardness equal to or higher than the material of the target 10. These devices 24, 24′ contact resp. the left and the right end zones 18 of the target 10. On rotation of the target 10, thin layers of material of the target 10 are removed. As a result, build up of unwanted dielectric material in the end zones 18 is reduced, if not avoided. In this way the risk for charging up and the related risk for arcing is reduced.

As an example, the material of the target 10 can be zinc and the contacting surface material of the devices 24, 24′ can be tungsten carbide.

### EXAMPLE 3

FIG. 4 illustrates a third example where material is applied to zones 20 of racetrack return of a target 10. Rolls 26, 26′ are applied respectively to the left and right zones of racetrack return 20, for example by means of a spring system (not shown). The surface of rolls 26, 26′ may have a linear speed which is different from the linear speed of the surface of target 10, so that there is a slip between the rolls 26, 26′ and the target 10. The rolls 26, 26′ are provided with a material of lower sputter rate and of lower hardness than the material of the target 10. On rotation of the target 10 and due to the lower hardness of the material on the rolls 26, 26′, material is applied to the complete circumference of the target 10. Due to the lower sputter rate of the applied material the sputter rate at the zones of racetrack return 20 slows down and the groove formation is reduced or avoided.

As a matter of example, the target 10 may be of zinc, tin, titanium or silicon, and the rolls 26, 26′ may be provided with graphite on their surface.

### EXAMPLE 4

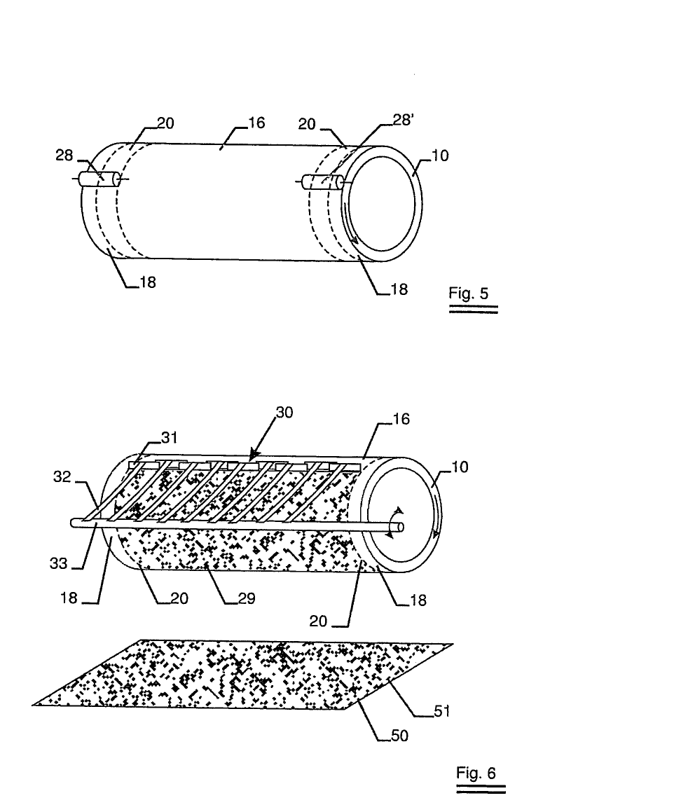

Example 4 is a combination of example 1 and example 3. FIG. 5 illustrates this fourth example where material is applied to both the zones of racetrack return 20 and the end zones 18 of a cylindrical rotating target 10. The application of the material may be done by means of two rolls 28, 28′.

### EXAMPLE 5

FIG. 6 illustrates a fifth example where material is removed from the erosion zone 16 of an ITO target 10. A moveable scraper 30 comprising different scraper blades 31 each attached to a blade spring 32 can be made to contact the erosion zone 16 and the zone of racetrack return 20 by turning the carrier rod 33. Preferably the blade springs are made of an electric insulating material. As explained hereabove, the surface of the ITO target shows the presence of nodules 29, which may cause arcing or inhomogeneities in the sputtered coating. The scraper 30 removes the nodules 29 upon rotation of the ITO target 10.

It will be clear from the above that during removal of material the target is preferably not in sputtering mode although this possibility is not excluded (depending on the position of the substrate vis-à-vis the electrode). Although the sputtering cycle is then stopped, the method does not necessitate the breaking of the vacuum or the demounting of the target for cleaning. The debris 51 can conveniently be collected on a collector plate 50 having substantially the same dimensions of a regular substrate and taking the place of the latter in order to prevent the pollution of the sputtering apparatus. The presence of the vacuum helps to prevent the dust propagation in the apparatus during cleaning.

In a first alternative embodiment (not shown), the scraper can consist of an elongated cylindrical metal brush that is pushed against the rotating target. The brush can on its turn be rotated against the target.

In a second alternative embodiment (not shown), the scraper may consist of a cutting tool that moves over the target much like a chisel moves over the workpiece in a lathe.

### EXAMPLE 6

FIG. 7 illustrates a sixth example where material is removed from rotating anodes 34, 34′. Next to a cathode target 10 two rotating cylindrical anodes 34, 34′ are provided. Brushes 36, 36 rub against respectively the left and the right anodes 34,34′. As the anodes rotate the whole circumferential surface of the anodes 34, 34′ is cleaned. Build up of dielectric material on the anodes 34 is avoided. The result is that the anodes continue to function and do not disappear.

As a matter of example, the anodes 34 can be made out of a stainless steel and the brushes 36, 36 can be made of high carbon steel. As an alternative, steel wool can be used to clean the anodes.

### EXAMPLE 7

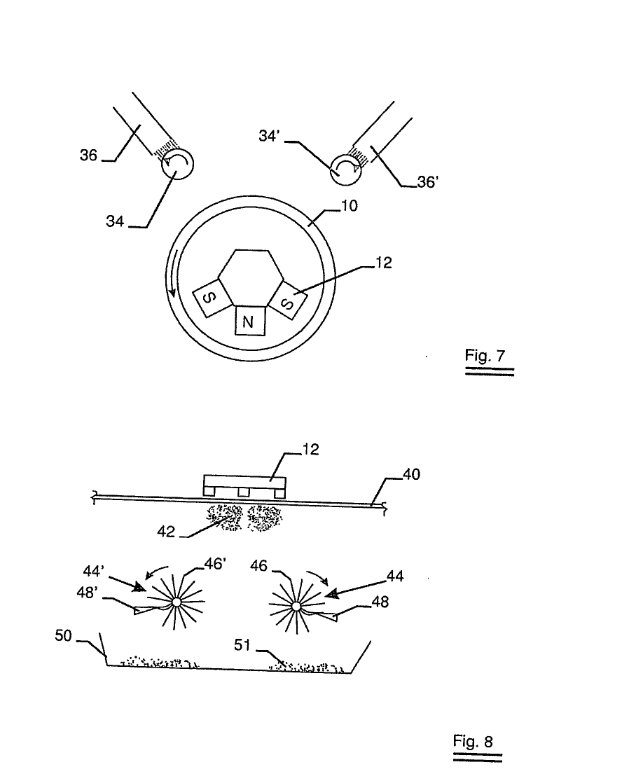

FIG. 8 visualises a seventh example with two collecting anodes 44, 44′. Each electrode is an anode in the form of an elongated cylindrical metal wire brush 44, 44′ that is rotating around its own axis. A plurality of metal wires 46, 46′ collect the target material removed from the planar target 40 by means of a plasma 42 that is confined by a magnetic array 12. The number of wires depicted is not corresponding to the true number of wires in the brush and their size and length is not drawn to scale. Whilst rotating, the wire brushes contact a device 48, 48′. The device bends the wire and thereby removes target material collected on the wire. The device is preferably made of an insulating material such as a ceramic material or the like. Again the debris 51 is collected on a collector plate 50 in order not to pollute the sputtering apparatus.

1. A method to improve the sputter deposition process, said method comprising the following steps:
a) providing a vacuum;
b) providing an electrode in said vacuum;
c) providing a substrate in said vacuum, said substrate having no contact with said electrode;
d) providing a device in said vacuum; said device being in relative motion to said electrode and being in mechanical contact with said electrode over a contact zone;
said device removing material from said electrode or said device applying material to said electrode, said material being in a solid state.

2. The method according to claim 1, wherein said device has a hardness, which is greater than, or equal to the hardness of the electrode or part thereof in order to remove material from said electrode.

3. The method according to claim 1, wherein said device has a hardness, which is smaller than, or equal to the hardness of the electrode or part thereof in order to apply material to said electrode.

4. The method according to claim 1, wherein said electrode is a cathode.

5. The method according to claim 4, wherein said cathode is a rotatable cylindrical target.

6. The method according to claim 1, wherein said electrode is an anode.

7. The method according to claim 6, wherein said anode is a vacuum chamber wall or shield.

8. The method according to claim 6, wherein said anode is a rotatable cylindrical tube.

9. The method according to claim 6, wherein said anode is a rotatable brush.

10. The method according to claim 4, wherein said target has an end zone that is not sputtered and wherein said contact zone overlaps with said end zone.

11. The method according to claim 4, wherein said target has a zone of race track return and wherein said contact zone overlaps with said zone of race track return.

12. The method according to claim 4, wherein said target has an erosion zone and wherein said contact zone overlaps with said erosion zone.

13. The method according to claim 12, wherein said target is an ITO target.

14. A method according to claim 1, wherein said device is intermittently in relative motion to said electrode and said device is intermittently in contact with said electrode.

15. A method according to claim 1, wherein said device is continuously in relative motion to said electrode and said device is intermittently in contact with said electrode.

16. A method according to claim 1, wherein said device is intermittently in relative motion to said electrode and said device is continuously in contact with said electrode.

17. A method according to claim 1, wherein said device is continuously in relative motion to said electrode and said device is continuously in contact with said electrode.
